(19) United States
(12) Patent Application Publication
(10) Pub. No.: US 2026/0247930 A1
(43) Pub. Date: Aug. 20, 2026

(54) METHOD FOR PRODUCING ELONGATE PATTERN FEATURES BY APPLYING DIRECTIONAL ETCHING

(71) Applicant: IMEC VZW, Leuven (BE)

(72) Inventor: Frederic Lazzarino, Hamme-Mille (BE)

(21) Appl. No.: 19/543,105

(22) Filed: Feb. 18, 2026

(30) Foreign Application Priority Data
Feb. 20, 2025 (EP) 25159219.2

(51) Int. Cl. H10P 76/40; H10P 50/00; H10P 50/28

(52) U.S. Cl. CPC H10P 76/4085; H10P 50/28; H10P 50/73; H10P 76/405

(57) ABSTRACT

A layer is produced on an etch stop layer formed on a support substrate. The layer is patterned by forming at least one opening having upright sidewalls through the full thickness of the layer. The opening is enlarged by a sequence of directional etch steps wherein the angle of incidence of the applied plasma beam is increased at each subsequent step compared to the previous step, so that the plasma beam impinges on the full height of the sidewall of the opening or enlarged opening at each step. Subsequent directional etch steps may be performed in the same scanning direction at each step, or the scanning direction may be changed at each step, or combinations of equal and differing scanning directions may be applied. The adjustment of the angle of incidence enables a higher etch rate in the scanning direction and thereby a higher obtainable elongation.

### CROSS-REFERENCE TO RELATED APPLICATION(S)

The present application is a non-provisional patent application claiming priority to European Patent Application No. 25159219.2, filed February 20, 2025, the contents of which are hereby incorporated by reference.

### FIELD OF THE DISCLOSURE

The present disclosure is related to semiconductor fabrication processes, in particular to patterning methods applicable for realizing nanometer-sized features in a patterned layer.

### BACKGROUND

Semiconductor fabrication processing relies on advanced lithography and etching technologies capable of realizing patterns at the nanometer-sized scale used (e.g., required) in the front-end-of-line and at the deepest levels of the back-end-of-line process sequences. Nevertheless, even the most advanced EUV lithography tools are limited in terms of the obtainable resolution, using (e.g., requiring) expensive multiple exposure methods for printing features smaller than the resolution limit.

Directional patterning techniques represent one way of overcoming these limitations. The term “directional patterning” encompasses directional etching and directional deposition.

Basic principles and configurations for realizing directional patterning are described, for example, in U.S. Patent Number 10,790,155. According to the example technology, a plasma beam is scanned relative to a substrate including a layer to be patterned. By tuning several parameters and conditions, a plasma beam containing etch species may be directed so that the beam etches a layer on the wafer at a (e.g., considerably) higher etch rate in the scanning direction than in directions orthogonal to the scanning direction. An (e.g., existing) opening in the layer may be stretched by scanning a plasma beam across the opening.

Directional etching facilitates patterning line features at sub-resolution pitch. Starting from a pattern of openings by anisotropic etching and a judicious arrangement of the openings, the openings are stretched to obtain lines at the (e.g., required) sub-resolution pitch. This approach is also described in U.S. Patent Number 10,790,155.

One challenge related to directional etching is that the etch rate in the direction perpendicular to the support substrate is not zero and facilitates thinning of the layer patterned by the directional etching process. This may limit obtainable elongation and make it challenging to obtain line features above a given length.

### SUMMARY

The disclosure relates to a method in accordance with the appended claims. A layer is produced on an etch stop layer formed on a support substrate. The layer is patterned by forming at least one opening having upright sidewalls through the full thickness of the layer. The opening is enlarged by a sequence of directional etch steps wherein the angle of incidence of an applied plasma beam is increased at each subsequent step compared to the previous step, so the plasma beam impinges on the full height of the sidewall of the opening or enlarged opening at each step. Subsequent directional etch steps may be performed in the same scanning direction at each step, or the scanning direction may be changed at each step, or combinations of equal and differing scanning directions may be applied to obtain various shapes of pattern features.

The adjustment of the angle of incidence provides a higher etch rate in the scanning direction and thereby provides a higher obtainable elongation (e.g., compared to methods wherein repeated directional etch steps are performed applying the same angle of incidence at each step).

The disclosure is related to a patterning method applicable in a semiconductor production process. The patterning method includes producing an etch stop layer on a support substrate, producing a layer on the etch stop layer, and patterning the layer to obtain a patterned layer including at least one opening having upright sidewalls and extending through the full thickness of the patterned layer. The patterning method further includes elongating, in the patterned layer, the at least one opening by directional etching (e.g., selectively) relative to the etch stop layer. The directional etching is performed with a sequence of (e.g., consecutive) directional etching steps under the influence of a plasma beam oriented according to an angle of incidence relative to the plane of the patterned layer and scanned in a scanning direction relative to the opening. The patterned layer is thinned progressively under the influence of the consecutive directional etch steps. In each step, an angle of incidence is applied that facilitates the beam to impinge on the full height of a sidewall of the opening at the start of the step. In each subsequent step, the angle of incidence is increased compared to the angle applied in the step (e.g., immediately) preceding the subsequent step, and the sequence continues until a predefined elongation of the opening is obtained.

According to an example embodiment, the scanning direction is changed at each subsequent step compared to the scanning direction applied in the step preceding the subsequent step.

According to an example embodiment, the scanning direction of each subsequent step is diametrically opposed to the scanning direction of the preceding step, so the pattern of geometrical features is a pattern of parallel lines.

According to an example embodiment, the scanning direction of one or more subsequent directional etch steps is (e.g., substantially) perpendicular to the scanning direction of the preceding step.

According to an example embodiment, the patterned layer is patterned according to a pattern including a regular array of the openings through the full thickness of the patterned layer. The array includes rows of aligned openings. The directional etch steps are performed in scanning directions aligned to the rows, until the enlarged openings merge into a set of parallel lines.

According to an example embodiment, an etch stop layer is produced on a target layer (e.g., present) on the support substrate. The layer produced in the etch stop layer is a mask layer The mask layer is patterned (e.g., according to any one of the preceding steps), followed by transferring. The pattern (e.g., finally) obtained in the mask layer is transferred to the target layer.

According to an example embodiment, the mask layer includes a stack of sublayers. The stack of sublayers includes, from bottom to top, a first hardmask layer of a first thickness, a second hardmask layer of a second thickness higher (e.g., greater) than the first thickness, a third hardmask layer of a third thickness (e.g., essentially) equal to the first thickness. The third hardmask layer is consumed during the patterning of the mask layer to form the at least one opening having upright sidewalls through the first and second hardmask layers.

### BRIEF DESCRIPTION OF THE FIGURES

The above, as well as additional, features will be better understood through the following illustrative and non-limiting detailed description of example embodiments, with reference to the appended drawings.

FIG. 1 shows the main components of a tool for directional etching.

FIGS. 2A, 2B and 2C show the process of directional etching.

FIGS. 3A and 3B show the shadow effect and how this can have a negative impact on a directional etching process.

FIGS. 4, 5, 6, 7, 8, 9, 10, 11 and 12 show a process sequence in accordance with an example embodiment of the present disclosure.

FIGS. 13, 14 and 15 show pattern features obtainable by alternative sequences of directional etching steps in accordance with example embodiments of the present disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the example embodiments set forth herein; rather, these embodiments are provided by way of example. Furthermore, like numbers refer to the same or similar elements or components throughout.

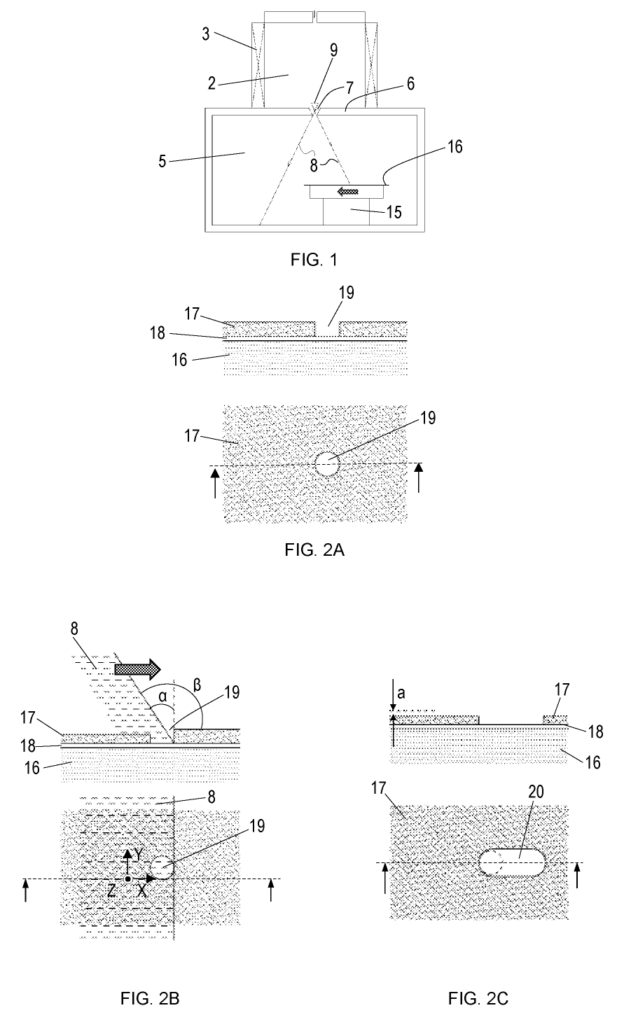

FIG. 1 shows a process tool 1 for applying a conventional directional etching technology. The disclosure is not limited to this directional etching technology. The tool includes a plasma chamber 2 surrounded by an RF coil 3 for generating a plasma in the chamber. A gas inlet 4 facilitates supplying a gaseous substance, while the overall pressure in the plasma chamber is kept at a (e.g., very) low to vacuum level by a vacuum pump installation (not shown). The plasma chamber 2 is separated from a process chamber 5 by a separating wall 6 including a slit 7, so ribbon plasma beams 8 may be emitted from the slit. The process chamber is also at a low to vacuum pressure. A meniscus 9 may be mounted in the vicinity of the slit 7 at a distance that may be set to control the propagation direction of the emitted beams 8. A wafer stage 15 is mounted in the process chamber 5. The wafer stage 15 is movable linearly as indicated by the arrow, so a wafer 16 held by the wafer stage may be moved relative to one of the beams 8, thereby creating the equivalent of the beam 8 scanned across the wafer 16.

Other directional etching technologies may be applied in the method according to the disclosure. Ion beam-based technologies include a method wherein a collimated beam of charged particles e.g. Ar+ is accelerated on a full wafer at a given angle of incidence. In the latter method, the wafer stage is not moving relative to the beam as the beam is impinging on the full wafer. According to another ion beam-based technology, a collimated beam of ionized gas clusters is accelerated to a spot and scanned across a wafer surface at a given angle of incidence. In the latter two technologies, the angle of incidence of the beam may be adjusted by tilting the wafer.

FIGS. 2A to 2C show the directional etching effect on a layer 17 formed on the wafer 16. The layer 17 is produced on an etch stop layer 18. Before applying the directional etch process, an opening 19 is formed in the layer 17 by standard lithography and etching, e.g., by direct ion etching (DIE). With reference to FIG. 2B, a plasma beam 8 is generated and directed at an angle of incidence α, provided as the angle between the beam 8 and the direction perpendicular to the surface of the layer 17. By moving the wafer stage 15 in the direction indicated in FIG. 1, the plasma beam 8 is scanned relative to the layer 17 in a scanning direction +X. The angle β between the beam 8 and the scanning direction X is an oblique angle equal to 90°+α. By applying a (e.g., suitable) combination of etch parameters such as the RF power, a DC bias voltage connected to the separator plate 6 and/or the wafer stage 15, the applied etch species, the angle of incidence α and the scanning speed, scanning the beam across the opening 19 has the effect of stretching the opening in the scanning direction, as shown in FIG. 2C. The directional etch process is selective with respect to the etch stop layer 18 so the layer remains (e.g., essentially) intact and prohibits etching of the underlying support substrate (e.g., wafer) 16. The etch rate in the X-direction is (e.g., considerably) higher than the etch rate in the Y and Z-directions. The result is an elongation of the opening 19 in the X-direction to form a line-shaped trench 20. In the Y-direction, the line is (e.g., slightly) larger than the original diameter of the opening 19, due to the non-zero etch rate in the Y direction. Etching in the Z-direction facilitates thinning of the layer 17 by a layer thickness reduction a.

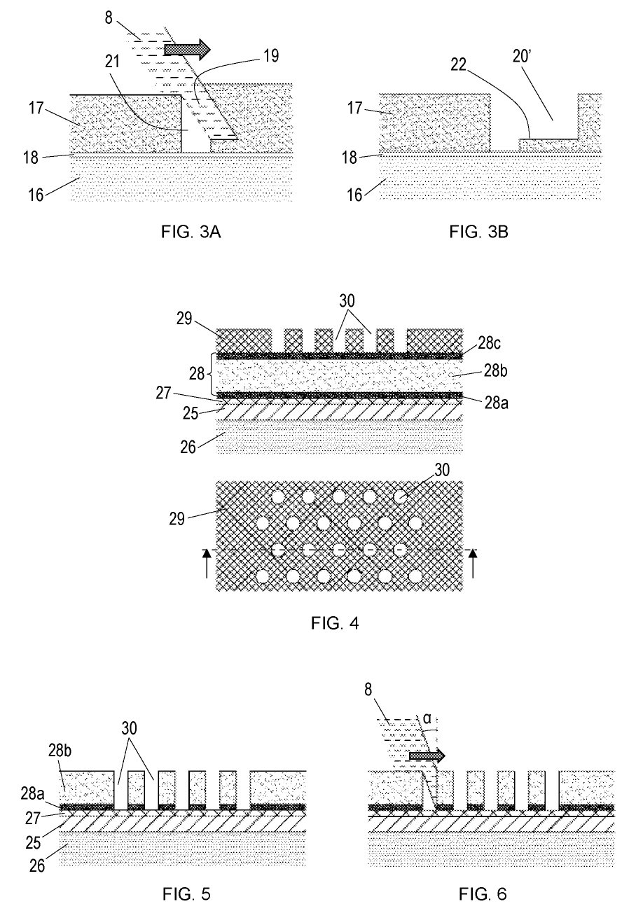

When the initial opening 19 is deeper, however, the beam may not be able to perform the directional etch process completely, as shown in FIGS. 3A and 3B, due to the so-called shadow-effect. As shown in FIG. 3A, the upstream side of the opening 19 creates a shadow area 21 where the beam cannot propagate. As the beam progresses in the scanning direction X, the shadow effect prohibits the beam from impinging on the full height of the sidewall of the elongated trench 20’ so a step 22 remains at the bottom of the trench, as shown in FIG. 3B.

This may be remedied by reducing the angle of incidence of the beam, e.g., orienting the beam closer to the direction perpendicular to the layer patterned by directional etching. This may also increase the etch rate in the Z-direction, so the layer is thinned faster. At the same time, the smaller angle of incidence may decrease the etch rate in the X-direction, e.g., the elongation may be slower. These effects make creating (e.g., significant) elongations starting from any given initial diameter of the openings challenging.

FIGS. 4 to 12 show a process sequence in accordance with an example embodiment of the present disclosure. The example embodiment relates to the elongation of openings arranged initially in a regular pattern of openings, but the disclosure is not limited thereto, and is applicable to any (e.g., regular or irregular) pattern of one or more openings.

The example embodiment may pattern a target layer 25 formed on a support substrate 26. The target layer 25 may be any layer that may be patterned in the course of a semiconductor fabrication process, for example, a dielectric layer formed in the course of the back end of line fabrication of integrated circuits produced on a silicon process wafer, and the dielectric layer may be patterned by creating parallel line-shaped trenches at a regular pitch, to be filled thereafter with metal to form conductive paths. The present disclosure is not limited to any type of layer to be patterned, nor to any stage within a semiconductor fabrication process.

In FIG. 4, a stack of several layers may be produced on top of the target layer 25. In direct contact with the target layer 25, an etch stop layer 27 is formed, followed by a mask layer 28 including three sublayers including a bottom hardmask layer 28a, a middle hardmask layer 28b, and a top hardmask layer 28c. A mask layer is provided as any layer configured to be patterned according to a given pattern whereafter the pattern is transferred to a layer lying underneath the mask layer. Transferring a pattern from a patterned mask layer to an underlying layer is provided as etching the underlying layer by an etch process that reproduces the mask pattern in the underlying layer. The transferring includes performing a tone reversal before transferring the pattern, for example, negative features (e.g., openings and trenches) are transformed to positive features (e.g., islands and lines). For example, if the mask layer is a pattern of trenches, the trenches may be filled with a material followed by the removal of the mask material, so the positive lines remain. These lines are (e.g., then) transferred to the underlying layer.

The stack of hardmask layers 28a, 28b, and 28c is one example embodiment of a mask layer. A mask layer may have other physical appearances within the wider scope of the present disclosure. For example, the mask layer may be a single layer, e.g., a layer of photoresist. The three-sublayer stack 28a, 28b, and 28c may be used to produce (e.g., very) small features, having dimensions in (e.g., the order of) nanometers. The present disclosure is not limited to any dimensions of the patterned features produced by the method of the disclosure.

The etch stop layer material 27 may depend on the hardmask stack material combination but may be a metal-based material (e.g., Ti, TiN, TiO₂, TiON, Ta, TaN), an aluminium-based dielectric material, or a Si-based material (e.g., amorphous Si). The bottom hardmask layer material 28a depends on the hardmask stack material combination but may be a dielectric material used in semiconductor fabrication (e.g., Spin on glass, SiOC, SiO₂, SiN, SiON, SiCN, SiOCN, SiC), or a metal-based material (e.g., Ti, TiN, TiO₂, TiON, Ta, TaN), or an aluminium-based dielectric material. The middle hardmask layer 28b may be an organic carbon-containing layer (e.g., amorphous carbon), Diamond (e.g., Carbon (DLC)), or Spin on Carbon (SOC). The top hardmask layer 28c may be the same material as the bottom layer 28a or formed of one of the materials cited as possible materials for the bottom layer. The thickness of the top and bottom layers may be the same and smaller than the thickness of the middle layer. In an example embodiment, the thickness of the top and bottom hardmask layers 28a and 28c may be in the range of about 10 nm to about 15 nm, while the thickness of the middle layer 28b may be in the range of about 50 nm to about 100 nm.

On top of the mask layer 28, a resist layer 29 is formed and patterned by (e.g., standard) lithography according to a pattern of openings. The pattern is a regular array of circular openings 30 of an equal diameter. In the example embodiment, the pattern is a hexagonal pattern, e.g., each opening 30 is surrounded by six other openings at regular angular and linear distances from a central opening. The disclosure is not limited to any pattern of openings, regular or irregular. For example, the openings may have a diameter of about 20 nm, with the center-to-center pitch of the array (e.g., distance between the centers of each pair of adjacent openings) at about 46 nm.

The pattern of openings is transferred to the mask layer 28. For example, the pattern of openings may be transferred to the mask layer 28 by first etching the top mask layer 28c relative to the resist layer 29 using a first etch method. Then the middle hardmask layer 28b is etched using a second etch method that also etches the resist layer 29. The resist layer 29 is therefore consumed as the openings are etched in the middle hardmask layer 28b. Then the bottom hardmask layer 28a is etched by a third etch method, while (e.g., simultaneously) consuming the top hardmask layer 28c. As shown in FIG. 5, the pattern of openings 30 has been transferred to the bottom hardmask layer 28a and the middle hardmask layer 28b, e.g., the openings 30 having upright sidewalls are formed through the hardmask layers 28a and 28b. The upright sidewalls may refer to sidewalls which are perpendicular to the plane of the support substrate 26 or close to (e.g., substantially) perpendicular, e.g., a small deviation from the geometrical perpendicular orientation.

The hardmask layers 28a and 28b are subjected to a directional etch step as described hereinabove, and as shown in FIG. 6. A directional etch beam 8 is scanned in the X-direction across the pattern of openings, thereby etching the hardmask layers 28a and 28b (e.g., selectively) with respect to the etch stop layer 27.

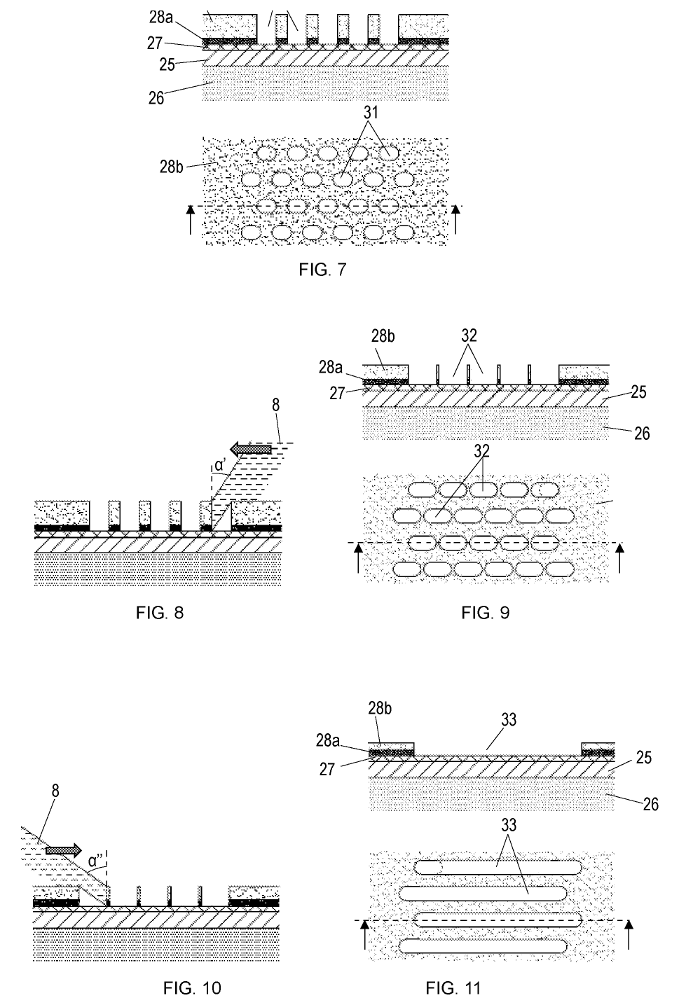

The angle of incidence α is such that the beam 8 impinges on the full height of the sidewall of the openings 30. After the passage of the beam, the openings 30 are enlarged as shown in FIG. 7. The middle hardmask layer 28b has been thinned by the directional etch process, for example, the original mask layer 28 is thinned, so the bottom hardmask layer 28a and a thinned remaining portion of the bottom hardmask layer 28b are left after the passage of the directional etch beam 8. The directional etch process has elongated the openings 30 to form a pattern of line portions 31 formed as trenches in the thinned mask layer. A small degree of etching in the Y-direction may take place due to a small etch rate in the Y-direction.

A second directional etch step is (e.g., then) applied by a plasma beam scanned in the opposite direction, as shown in FIG. 8. The angle of incidence α’ is higher than the angle of incidence α applied in the first directional etch step while (e.g., still) impinging on the full height of the sidewall of the elongated openings (e.g., line portions 31). The higher angle of incidence may be applied because of the thinning of the mask layer in the first directional etch step, i.e., the beam may be oriented closer to horizontal without the (e.g., negative) impact of the shadow effect.

After the second etch step, the elongated openings are further elongated to form line portions 32, and the mask layer is further thinned, as shown in FIG. 9. As the angle of incidence has increased, e.g., the beam is oriented closer to the horizontal, the etch rate in the X-direction is higher, so the elongation of the line portions is higher than in the first directional etch step.

In FIG. 10, a final directional etch step is (e.g., then) applied by scanning a plasma beam in a direction opposite to the scanning direction of the previous step(s). The angle of incidence α’’ is again higher than the angle α’ applied in the previous step(s), as provided by the further thinning of the mask layer.

As shown in FIG. 11, the line portions 32 are (e.g., again) enlarged and merge into a set of parallel line-shaped trenches 33 in the hardmask layers 28a and 28b. The latter (e.g., mask layer) is further thinned but now at a lower etch rate than those of the previous directional etch steps.

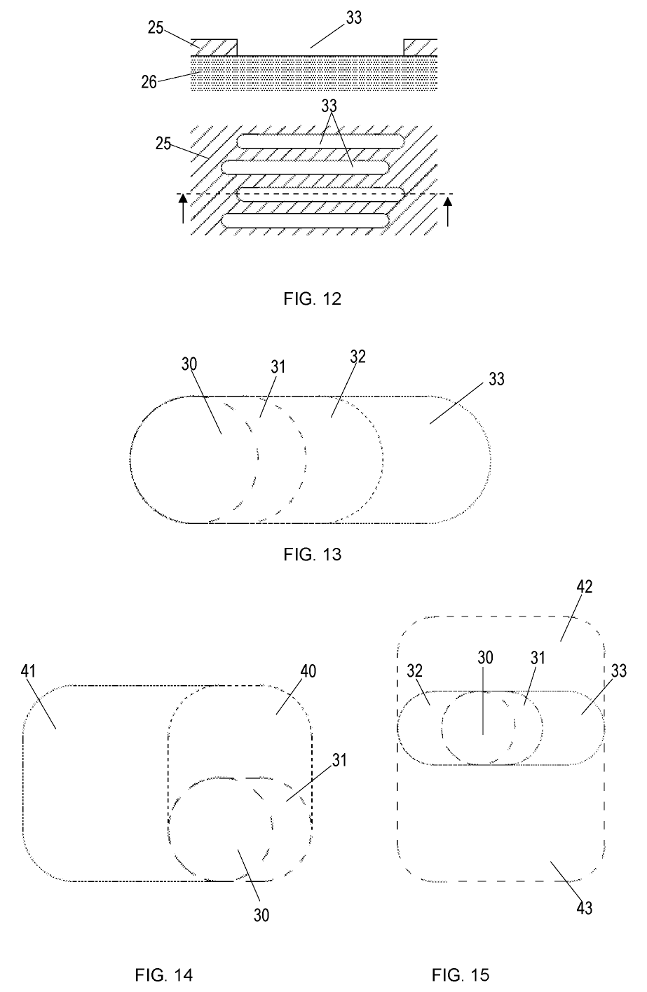

The final line pattern of line-shaped trenches 33 is (e.g., then) transferred to the etch stop layer 27 and to the target layer 25, as shown in FIG. 12. Any remaining portions of the etch stop layer 27 and the mask layer 28 may be stripped after the pattern transfers to the target layer 25.

The adjustment of the angle of incidence at each subsequent directional etching step increases the etch rate in the scanning direction progressively, which also increases the obtainable elongation, while thinning of the patterned layer is progressively less, as the beam is oriented more (e.g., and more) horizontally.

In the example embodiment, each subsequent directional etching step may be performed by scanning in a direction diametrically opposed to the scanning direction in the previous step(s). In practice, using a tool as shown in FIG. 1, this may be done by rotating the wafer stage 180° after a directional etch step and before the next directional etch step and performing at a higher angle of incidence. The angle of incidence may be adjusted, for example, by adjusting the position of the meniscus 9.

The above-described method steps are applicable regardless of the directional etch technology used. When applying a collimated beam that impinges on a full wafer, the beam is not scanned as indicated by the arrows in FIGS. 6, 8 and 10, but the effect of the beam is the same. Changing the angle of incidence may be done by tilting the wafer. When applying a collimated beam of ionized gas clusters on a spot of the wafer, the beam may be scanned as shown in the drawings, while the angle adjustment may also be done by tilting the wafer. The process sequence may be continued until a predefined elongation is obtained. Any realistically applicable number of directional etch steps may thus be applied. Due to the adjustment of the angle of incidence, the obtainable elongation is higher compared to a sequence wherein the same angle of incidence is applied at each directional etch step.

The disclosure is not limited to a process sequence wherein the consecutive directional etch steps are performed on a mask layer followed by the transfer of the mask pattern to a target layer. The consecutive etch steps may be performed (e.g. directly) on a target layer.

The disclosure is not limited to the above-described sequence wherein the scanning direction is reversed 180° at each directional etch step. The same scanning direction may be applied at each directional etch step, as shown schematically in FIG. 13. FIG. 13 shows three consecutive elongations 31, 32, and 33, starting from a circular opening 30, elongated each time by scanning in the same direction at (e.g., progressively) increasing angles of incidence.

The scanning directions oriented at angles other than 0° or 180° (e.g., relative to each other) may be applied in the consecutive directional etch steps.

FIG. 14 shows an example embodiment of a circular opening 30 first elongated to a line portion 31 in a first directional etch step. The line portion 31 is elongated to form a rectangular pattern feature 40 (e.g., with rounded corners) by scanning in a scanning direction oriented at 90° with respect to the previous step. In the last step, the scanning direction is again rotated to 90° with respect to the previous step, and the angle of incidence is increased, resulting in an enlarged rectangular feature 41.

In the example embodiment shown in FIG. 15, the circular opening 30 is first enlarged by the sequence shown in FIGS. 4 to 12. In the sequence, each scanning is diametrically opposed to the previous step and progressively increases the angle of incidence until reaching the line portion 33. The line portion is (e.g., then) enlarged in the direction oriented 90° to the previous scanning direction to a rectangular portion 42. The line portion is thereafter enlarged in the diametrically opposed direction and with a larger angle of incidence than the previous step, to a final rectangular portion 43.

Other combinations of consecutive scanning directions and resulting pattern features may be applied within the scope of the present disclosure.

In the example embodiment shown in FIGS. 4 to 12, the angle of incidence may be increased each time to a maximum angle that (e.g., still) impinges on the full height of the opening at the beginning of the directional etch step. The disclosure does not exclude applying an angle of incidence lower than the maximum, while (e.g., still) higher (e.g., greater) than the angle applied in the preceding step. The angle of incidence is increased at each step while impinging on the full height of the sidewall at the start of each step.

While some example embodiments have been shown and described in detail in the appended drawings and the foregoing description, the illustration and description are to be considered illustrative and not restrictive. Other variations to the disclosed embodiments may be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A patterning method used in a semiconductor production process, the method comprising:
producing an etch stop layer on a support substrate,
producing a layer on the etch stop layer,
patterning the layer to obtain a patterned layer comprising at least one opening having upright sidewalls and extending through a thickness of the patterned layer,
elongating the at least one opening in the patterned layer by directional etching relative to the etch stop layer, wherein the directional etching is performed with a plasma beam oriented according to an angle of incidence relative to a plane of the patterned layer and scanned in a scanning direction relative to the at least one opening until a predefined elongation of the at least one opening is obtained.

2. The method according to claim 1, further comprising thinning the patterned layer.

3. The method according to claim 1, wherein the directional etching further comprises applying the angle of incidence for the plasma beam to impinge on a height of one of the upright sidewalls of the at least one opening.

4. The method according to claim 1, wherein the directional etching further comprises increasing the angle of incidence while elongating the at least one opening in the patterned layer by directional etching.

5. The method according to claim 1, wherein the scanning direction is a first scanning direction, and the first scanning direction is changed to a second scanning direction while elongating the at least one opening in the patterned layer by directional etching.

6. The method according to claim 5, wherein the second scanning direction is diametrically opposed to the first scanning direction.

7. The method according to claim 6, further comprising forming a pattern of parallel lines.

8. The method according to claim 5, wherein the second scanning direction is perpendicular to the first scanning direction.

9. The method according to claim 1, wherein the at least one opening comprises a plurality of openings, the patterned layer is patterned according to a pattern comprising a regular array of the plurality of openings.

10. The method according to claim 9, wherein each opening of the plurality of openings is formed through the thickness of the patterned layer.

11. The method according to claim 10, wherein the array comprises rows of aligned openings.

12. The method according to claim 11, wherein the directional etching is further performed in a plurality of scanning directions aligned to the rows until the openings merge into a set of parallel lines.

13. The method according to claim 1, wherein the etch stop layer is produced on a target layer provided on the support substrate.

14. The method according to claim 13, wherein the layer produced in the etch stop layer produces a mask layer.

15. The method according to claim 14, further comprising patterning the mask layer.

16. The method according to claim 15, further comprising transferring a pattern from patterning the mask layer to the target layer.

17. The method according to claim 16, wherein the mask layer comprises a stack of sublayers.

18. The method according to claim 17, wherein the stack of sublayers comprise:
a first hardmask layer of a first thickness;
a second hardmask layer of a second thickness greater than the first thickness; and
a third hardmask layer of a third thickness substantially equal to the first thickness.

19. The method according to claim 18, wherein the third hardmask layer is consumed during patterning of the mask layer to form the at least one opening having upright sidewalls through the first and second hardmask layers.

20. The method according to claim 18, wherein the stack of sublayers is positioned in the order of the first hardmask layer, the second hardmask layer, and the third hardmask layer from bottom to top.
